(19) United States
(12) Patent Application Publication
(10) Pub. No.: US 2026/0075791 A1
(43) Pub. Date: Mar. 12, 2026

(54) SEMICONDUCTOR DEVICE

(71) Applicant: Samsung Electronics Co., Ltd., Suwon-si (KR)

(72) Inventors: Seung CHOI, Suwon-si (KR); Jae Hyun LIM, Suwon-si (KR); Byung Sung KIM, Suwon-si (KR); Tae Hyung KIM, Suwon-si (KR)

(73) Assignee: Samsung Electronics Co., Ltd., Suwon-si (KR)

(21) Appl. No.: 19/078,968

(22) Filed: Mar. 13, 2025

(30) Foreign Application Priority Data
Sep. 11, 2024 (KR) 10-2024-0123691

(51) Int. Cl. H10B 10/00

(52) U.S. Cl. CPC H10B 10/18; H10B 10/125

(57) ABSTRACT

A semiconductor device includes a cell array area including unit memory cells arranged two-dimensionally along a first direction and a second direction intersecting each other, a first peripheral circuit area including first unit peripheral cells arranged along the second direction, the first peripheral circuit area and the cell array area arranged along the first direction, and a second peripheral circuit area including second unit peripheral cells arranged along the second direction, the first peripheral circuit area interposed between the cell array area and the second peripheral circuit area, wherein in the second direction, a first unit cell height of each of the unit memory cells and a second unit cell height of each of the first unit peripheral cells are equal to each other, and a third unit cell height of each of the second unit peripheral cells is smaller than the second unit cell height.

### CROSS-REFERENCE TO RELATED APPLICATION

This application claims priority from Korean Patent Application No. 10-2024-0123691 filed on Sep. 11, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to semiconductor devices. More specifically, the present disclosure relates to semiconductor devices including a SRAM (static random access memory) element and/or a logic element.

### Description of Related Art

Due to characteristics such as miniaturization, multi-functionality, and/or lower manufacturing cost of a semiconductor device, the semiconductor device is receiving attention as an important element in the electronics industry. The semiconductor devices may be classified into a semiconductor memory device that stores therein logic data, a semiconductor logic device that performs computational processing of logic data, and a hybrid semiconductor device including a memory element and a logic element.

As the electronics industry is highly developed, the demand for the characteristics of the semiconductor device is increasing. For example, the demand for higher reliability, higher speed, and/or multi-functionality of the semiconductor device is increasing. In order to meet these demanded characteristics, structures within the semiconductor device are becoming increasingly complex and more highly integrated.

### SUMMARY

Some example embodiments of the present disclosure provide semiconductor devices with improved performance and/or integration.

Example embodiments of the present disclosure are not limited to the example embodiments mentioned in the present disclosure, and other example embodiments not mentioned may be clearly understood by those skilled in the art from descriptions as set forth below.

According to an example embodiment of the present disclosure, a semiconductor device may include a cell array area including a plurality of unit memory cells arranged two-dimensionally along a first direction and a second direction intersecting each other, a first peripheral circuit area including a plurality of first unit peripheral cells arranged along the second direction, the first peripheral circuit area and the cell array area arranged along the first direction, and a second peripheral circuit area including a plurality of second unit peripheral cells arranged along the second direction, the first peripheral circuit area interposed between the cell array area and the second peripheral circuit area, wherein a first unit cell height of each of the unit memory cells in the second direction and a second unit cell height of each of the first unit peripheral cells in the second direction are equal to each other, and wherein a third unit cell height of each of the second unit peripheral cells in the second direction is smaller than the second unit cell height.

According to an example embodiment of the present disclosure, there may be provided a semiconductor device including a memory cell, an upper peripheral cell, and a first lower peripheral cell sequentially arranged along a first direction. The semiconductor device may include a substrate, a first upper active pattern and a second upper active pattern on a first area of the substrate at which the upper peripheral cell is provided, the first upper active pattern and the second upper active pattern extending in the first direction and being spaced apart from each other in a second direction intersecting the first direction, a first gate structure on the first upper active pattern and the second upper active pattern and extending in the second direction, a first lower active pattern and a second lower active pattern on a second area of the substrate, at which the first lower peripheral cell is provided, the first lower active pattern and the second lower active pattern extending in the first direction and being spaced apart from each other in the second direction, and a second gate structure on the first lower active pattern and the second lower active pattern and extending in the second direction, wherein a first unit cell height of the memory cell in the second direction and a second unit cell height of the upper peripheral cell in the second direction are equal to each other, and wherein the first upper active pattern overlaps at least a portion of the first lower active pattern and at least a portion of the second lower active pattern in the first direction.

According to an example embodiment of the present disclosure, there may be provided a semiconductor device including a first area and a second area arranged along a first direction, and a third area interposed between the first area and the second area. The semiconductor device may include a substrate, first and second upper active patterns on a first portion of the substrate corresponding to the first area, the first and second upper active patterns extending in the first direction and arranged along a second direction intersecting the first direction, a first gate structure on the first and second upper active patterns and extending in the second direction, first to fourth lower active patterns on a second portion of the substrate corresponding the second area, the first to fourth lower active patterns extending in the first direction and arranged sequentially along the second direction, a second gate structure on the first to fourth lower active patterns and extending in the second direction, a first connection pattern on a third portion of the substrate corresponding to the third area, the first connection pattern connecting the first upper active pattern, the first lower active pattern, and the second lower active pattern to each other, a second connection pattern on the third portion of the substrate corresponding to the third area, the second connection pattern connecting the second upper active pattern, the third lower active pattern, and the fourth lower active pattern to each other, a first power wiring extending in the first direction across the first to third areas and configured to receive a first power voltage, and a second power wiring extending in the first direction across the first to third areas and configured to receive a second power voltage different from the first power voltage, wherein each of the first upper active pattern, the first lower active pattern, and the fourth lower active pattern includes a channel area of an NFET, and wherein each of the second upper active pattern, the second lower active pattern, and the third lower active pattern includes a channel area of a PFET.

### BRIEF DESCRIPTION OF DRAWINGS

The above and other aspects and features of the present disclosure will become more apparent by describing in detail some example embodiments thereof with reference to the attached drawings, in which:

FIG. 1 is an example block diagram illustrating a semiconductor device according to some example embodiments.

FIG. 2 is a conceptual plan view illustrating a semiconductor device according to some example embodiments.

FIG. 3 is an example circuit diagram illustrating a unit memory cell of FIG. 2.

FIG. 4 is an example layout diagram illustrating the semiconductor device of FIG. 2.

FIG. 5A and FIG. 5B are schematic cross-sectional views taken along lines A1-A1 and B1-B1 of FIG. 4, respectively.

FIG. 6A and FIG. 6B are schematic cross-sectional views taken along lines A2-A2 and B2-B2 of FIG. 4, respectively.

FIG. 7A and FIG. 7B are schematic cross-sectional views taken along lines A3-A3 and B3-B3 of FIG. 4, respectively.

FIG. 8 is a partial layout diagram illustrating active patterns of FIG. 4.

FIGS. 9 to 12 are other various example layout diagrams for illustrating semiconductor devices according to some example embodiments, respectively.

FIG. 13 is a conceptual plan view illustrating a semiconductor device according to some example embodiments.

FIG. 14 and FIG. 15 are various example layout diagrams illustrating the semiconductor device of FIG. 13.

FIG. 16 is a conceptual plan view illustrating a semiconductor device according to some example embodiments.

FIG. 17 is an example layout diagram illustrating the semiconductor device of FIG. 16.

### DETAILED DESCRIPTIONS

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

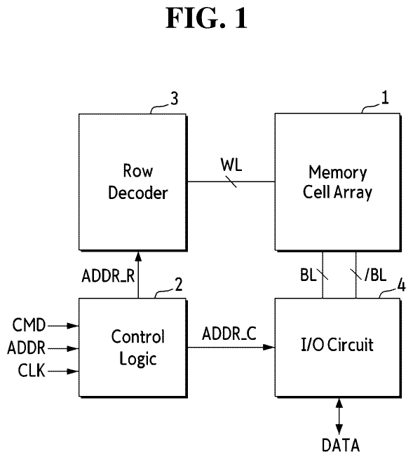

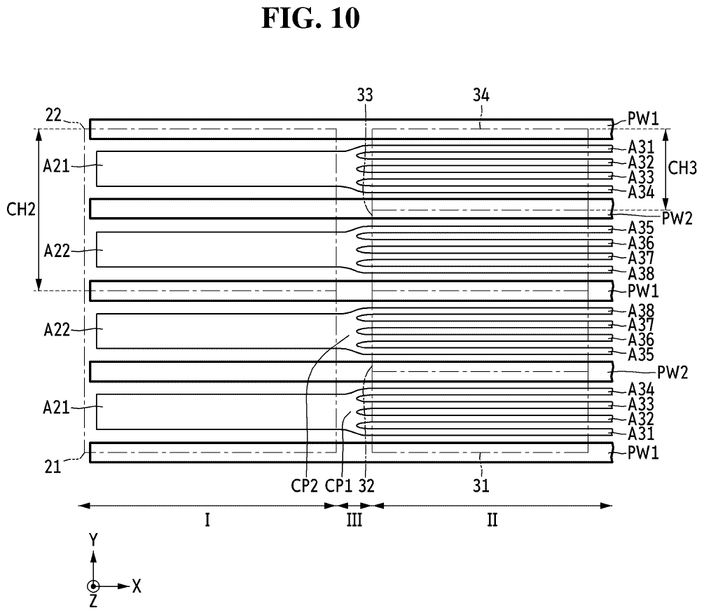

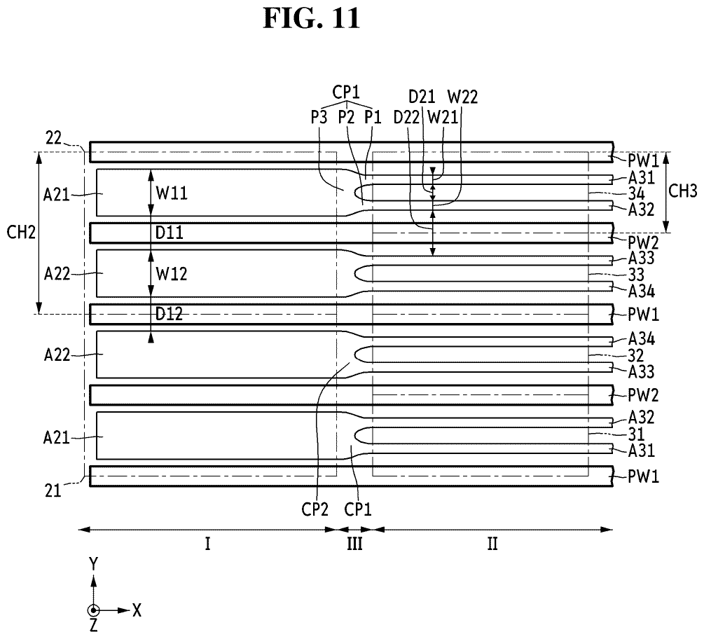

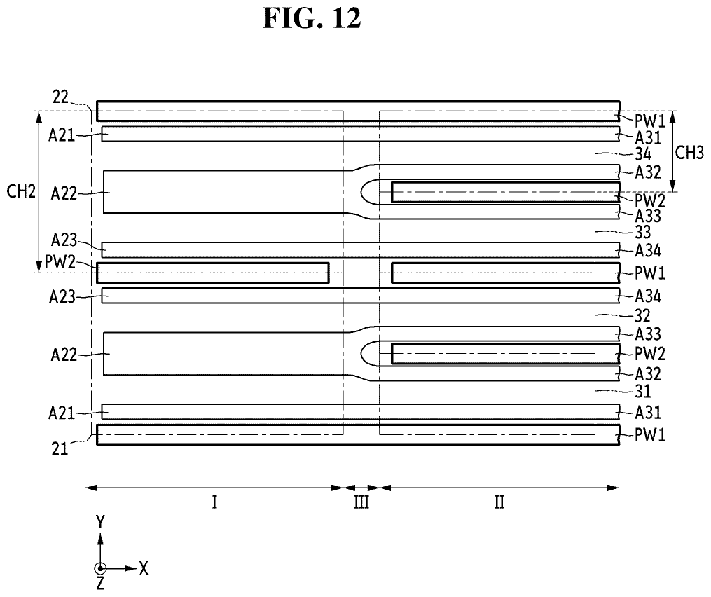

Hereinafter, with reference to FIGS. 1 to 17, semiconductor devices according to some example embodiments are described.

FIG. 1 is an example block diagram illustrating a semiconductor device according to some example embodiments.

Referring to FIG. 1, a semiconductor device according to some example embodiments includes a memory cell array 1, a control logic 2, a row decoder 3, and an input/output circuit 4.

The memory cell array 1 may include a plurality of memory cells, each storing therein 1 bit of data. In descriptions as set forth below, an example in which each memory cell is embodied as a SRAM (Static Random Access Memory) is described. However, this is only an example. In another example, each memory cell may be embodied as one of various other memory devices, such as DRAM (Dynamic Random Access Memory), NAND Flash Memory, NOR Flash Memory, RRAM (Resistive Random Access Memory), FRAM (Ferroelectric Random Access Memory), PRAM (Phase Change Random Access Memory), or MRAM (Magnetic Random Access Memory).

The control logic 2 may receive a command CMD, an address ADDR, and a clock CLK from an external device (e.g., a host, a CPU (Central Processing Unit), or a memory controller). The command CMD may include an instruction indicating an operation on the memory cell array 1. The address ADDR may include a row address ADDR_R indicating a row of memory cells to operate and a column address ADDR_C indicating a column of memory cells to operate. The control logic 2 may provide the row address ADDR_R to the row decoder 3 and the column address ADDR_C to the input/output circuit 4. The control logic 2 may control the operation of the memory cell array 1 based on a clock CLK received from the external device.

The row decoder 3 may be connected to the memory cell array 1 via a plurality of word-lines WL. The row decoder 3 may select at least one of the plurality of word-lines WL connected to the memory cell array 1 based on the row address ADDR_R provided from the control logic 2. For example, the row decoder 3 may apply voltage to the selected word-line WL to activate the same.

The input/output circuit 4 may be connected to the memory cell array 1 via a plurality of bit-lines BL and a plurality of complementary bit-lines/L. In some example embodiments, the input/output circuit 4 may include a column decoder, a sense amplifier, an input/output (I/O) buffer, a latch, and a write driver.

The column decoder of the input/output circuit 4 may select at least one of the plurality of bit-lines BLs and/or at least one of the plurality of complementary bit-lines/Ls based on the column address ADDR_C provided from the control logic 2. For example, the column decoder may apply voltage to the selected bit-line BL and/or the selected complementary bit-line/L to activate the same.

When a write operation is performed in response to the command CMD and the address ADDR, the input/output circuit 4 may receive data DATA from the external device. The input/output buffer of the input/output circuit 4 may temporarily store therein the received data DATA. The data DATA temporarily stored in the input/output buffer may be written to the memory cell array 1 through the write driver of the input/output circuit 4.

When a read operation is performed in response to the command CMD and the address ADDR, the sense amplifier of the input/output circuit 4 may detect and amplify the data DATA stored in the memory cell array 1. The input/output buffer of the input/output circuit 4 may temporarily store therein the data DATA detected by the sense amplifier. The data DATA temporarily stored in the input/output buffer may be provided to the external device in response to a request from the external device.

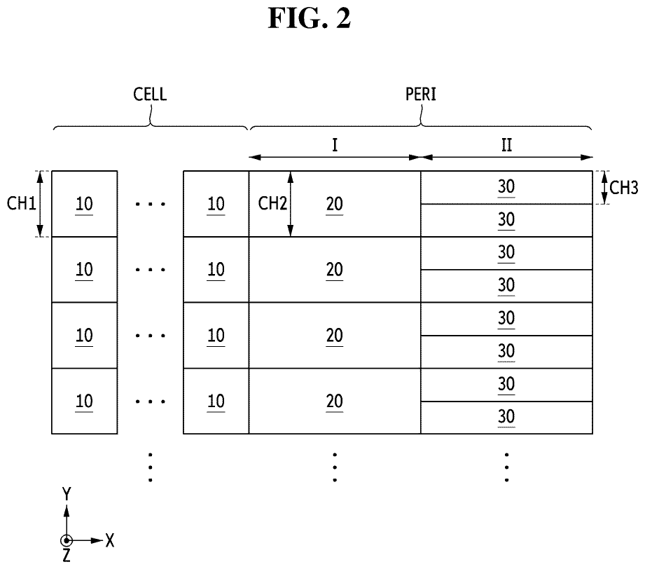

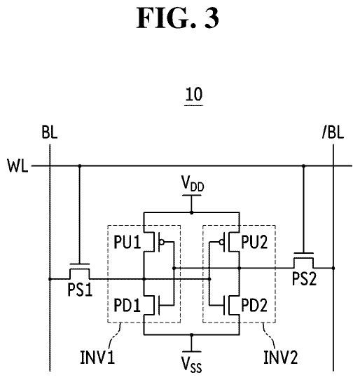

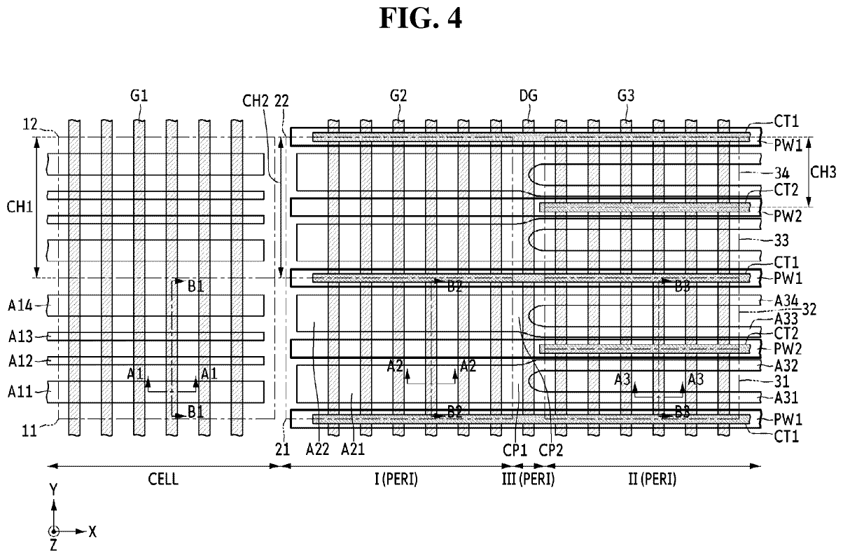

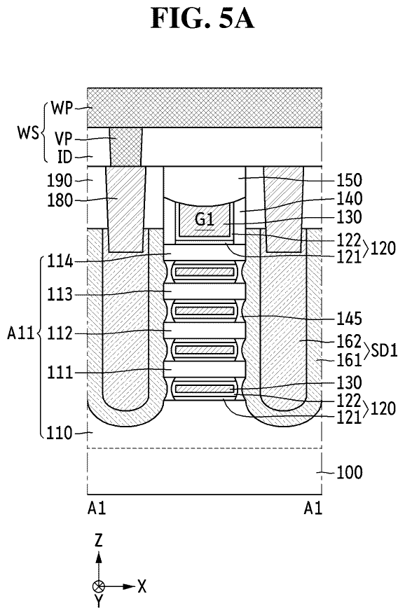

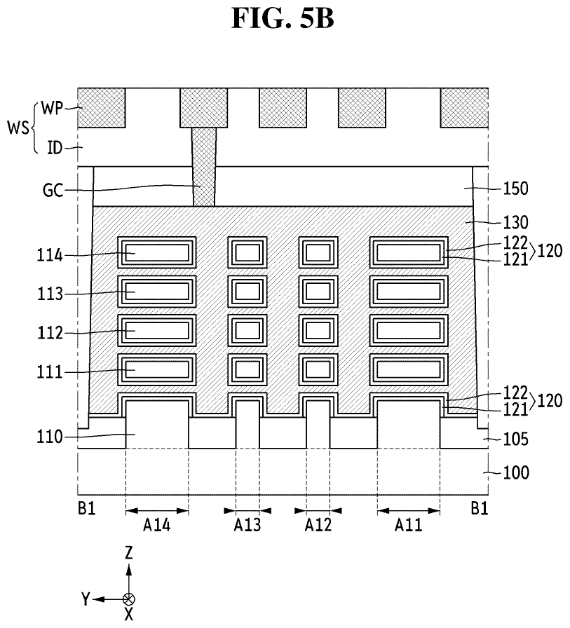

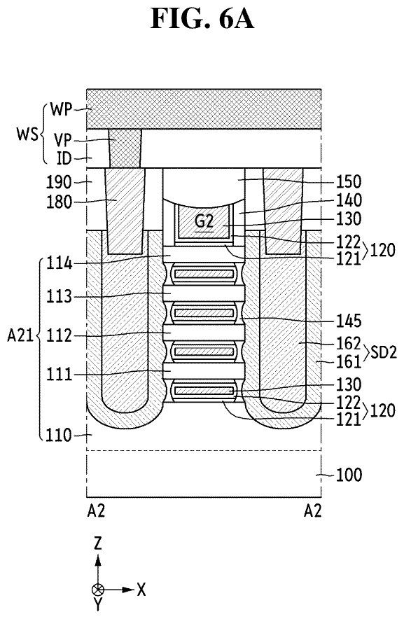

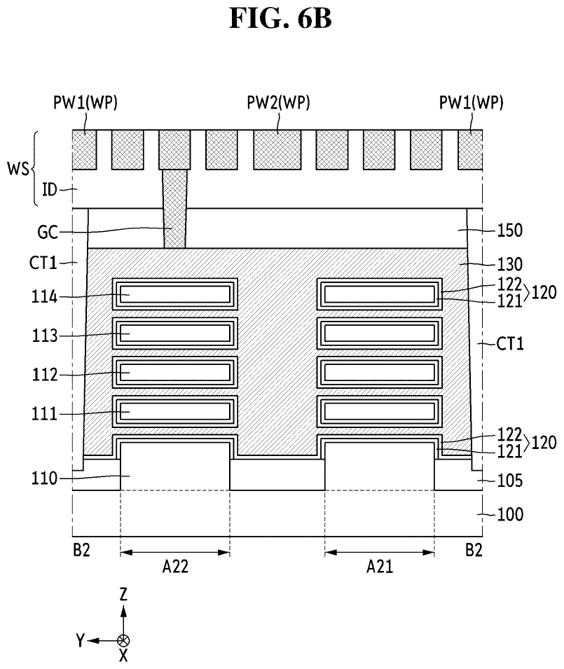

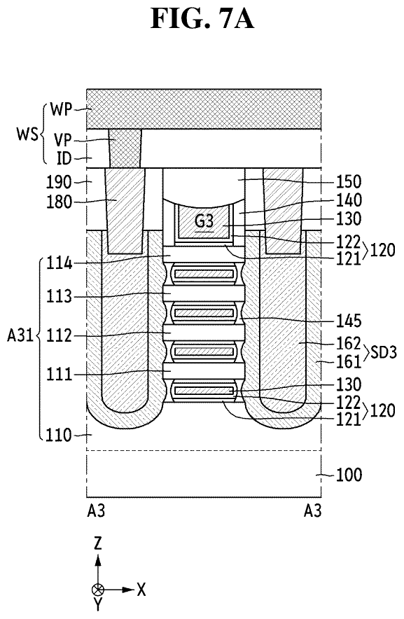

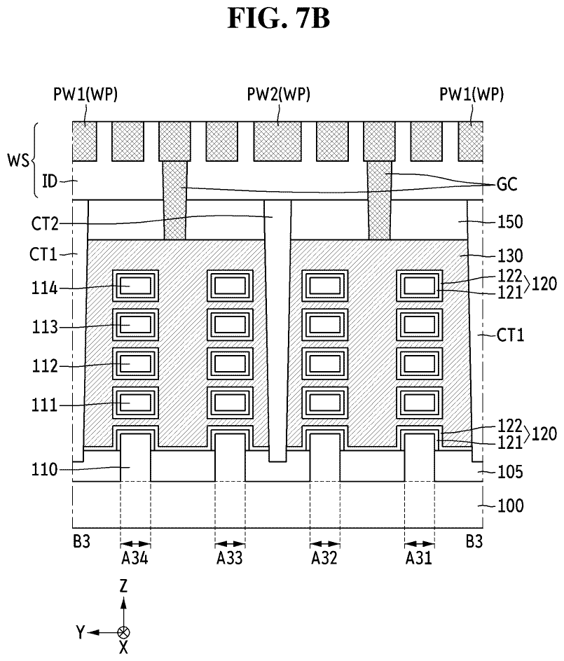

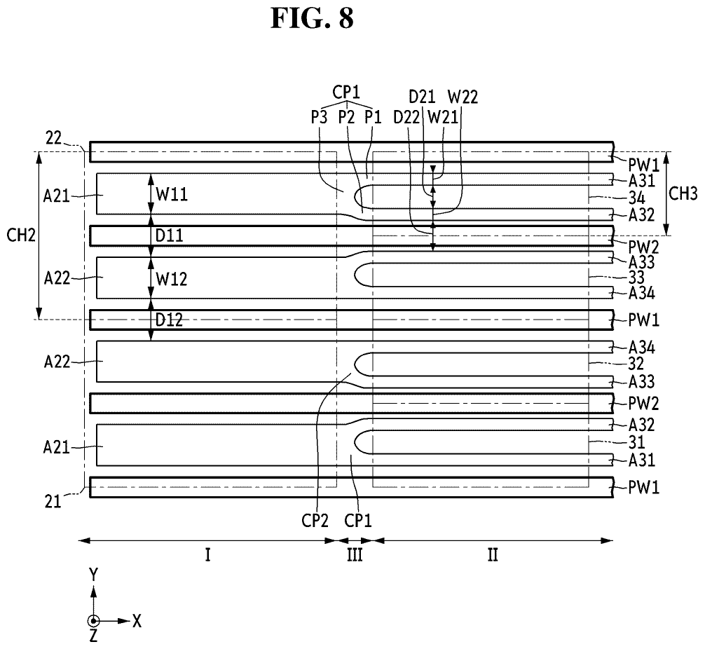

FIG. 2 is a conceptual plan view illustrating a semiconductor device according to some example embodiments. FIG. 3 is an example circuit diagram illustrating a unit memory cell of FIG. 2. FIG. 4 is an example layout diagram illustrating the semiconductor device of FIG. 2. FIG. 5A and FIG. 5B are schematic cross-sectional views taken along lines A1-A1 and B1-B1 of FIG. 4, respectively. FIG. 6A and FIG. 6B are schematic cross-sectional views taken along lines A2-A2 and B2-B2 of FIG. 4, respectively. FIG. 7A and FIG. 7B are schematic cross-sectional views taken along lines A3-A3 and B3-B3 of FIG. 4, respectively. FIG. 8 is a partial layout diagram illustrating active patterns of FIG. 4.

Referring to FIG. 1 and FIG. 2, the semiconductor device according to some example embodiments includes a memory cell area CELL and a peripheral circuit area PERI.

The memory cell area CELL may include a plurality of unit memory cells 10 arranged two-dimensionally. For example, the plurality of unit memory cells 10 may be arranged in a matrix form along a first direction X and a second direction Y intersecting each other. The memory cell area CELL may be included in the memory cell array 1 of FIG. 1.

The peripheral circuit area PERI may be formed around the memory cell area CELL. Control elements and dummy elements may be formed in the peripheral circuit area PERI to control an operation of the unit memory cells 10 formed in the memory cell area CELL. For example, the peripheral circuit area PERI may include at least some of the control logic 2, the row decoder 3, and/or the input/output circuit 4 as described above using FIG. 1.

In some example embodiments, the peripheral circuit area PERI may include a first area I and a second area II arranged along the first direction X from the memory cell area CELL. The first area I and the second area II may be arranged sequentially from the memory cell area CELL. For example, the first area I may be interposed between the memory cell area CELL and the second area II in the first direction X.

The first area I may include a plurality of first unit peripheral cells 20 arranged along the second direction Y. The second area II may include a plurality of second unit peripheral cells 30 arranged along the second direction Y.

In some example embodiments, the first area I and the second area II may be included in the input/output circuit 4 of FIG. 1. For example, the first area I and the second area II may be electrically connected to the memory cell area CELL via the bit-line BL and the complementary bit-line/L extending in the first direction X.

Each of the unit memory cells 10 may have a first unit cell height CH1. Each of the first unit peripheral cells 20 may have a second unit cell height CH2. Each of the second unit peripheral cells 30 may have a third unit cell height CH3. In this regard, the cell height means a length in the second direction Y of each of the unit cells 10 repeatedly arranged in the second direction Y, a length in the second direction Y of each of the unit cells 20 repeatedly arranged in the second direction Y, and a length in the second direction Y of each of the unit cells 30 repeatedly arranged in the second direction Y.

In some example embodiments, the first unit cell height CH1 and the second unit cell height CH2 may be equal to each other. In this case, the number of unit memory cells 10 and the number of first unit peripheral cells 20 may have a 1 to 1 correspondence.

In some example embodiments, the third unit cell height CH3 may be smaller than the second unit cell height CH2. In this case, the number of first unit peripheral cells 20 and the number of second unit peripheral cells 30 may have a 1 to N correspondence. In this regard, N is a rational number exceeding 1.

The first unit peripheral cells 20 and the second unit peripheral cells 30 will be described in more detail with reference to FIG. 3 to FIG. 8.

Referring to FIG. 1 to FIG. 3, in the semiconductor device according to some example embodiments, each unit memory cell 10 includes a pair of inverters INV1 and INV2 connected in parallel to each other and disposed between and connected to a power node V_{DD} and a ground node V_{SS}, and a first pass transistor PS1 and a second pass transistor PS2 connected to output nodes of the inverters INV1 and INV2, respectively.

In order to configure one latch circuit, an input node of the first inverter INV1 may be connected to an output node of the second inverter INV2, and an input node of the second inverter INV2 may be connected to an output node of the first inverter INV1.

The first inverter INV1 may include a first pull-up transistor PU1 and a first pull-down transistor PD1 connected in series to each other and disposed between and connected to the power node V_{DD} and the ground node V_{SS}. The second inverter INV2 may include a second pull-up transistor PU2 and a second pull-down transistor PD2 connected in series to each other and disposed between and connected to the power node V_{DD} and the ground node V_{SS}. Each of the first pull-up transistor PU1 and the second pull-up transistor PU2 may be a P-type Field Effect Transistor (PFET), and each of the first pull-down transistor PD1 and the second pull-down transistor PD2 may be an N-type Field Effect Transistor (NFET).

The first pass transistor PS1 may connect the bit-line BL to the output node of the first inverter INV1. The second pass transistor PS2 may connect the complementary bit-line/L to the output node of the second inverter INV2. A gate of the first pass transistor PS1 and a gate of the second pass transistor PS2 may be connected to a word-line WL.

Referring to FIG. 1 to FIG. 8, the semiconductor device according to some example embodiments includes a substrate 100, a field insulating film 105, first active patterns A11 to A14, second active patterns A21 and A22, third active patterns A31 to A34, first gate structures G1, second gate structures G2, third gate structures G3, a first source/drain area SD1, a second source/drain area SD2, a third source/drain area SD3, a source/drain contact 180, an interlayer insulating film 190, and a wiring structure WS.

The substrate 100 may be made of or include bulk silicon or SOI (silicon-on-insulator). In some example embodiments, the substrate 100 may be embodied as a silicon substrate, or may be made of or include a material other than silicon, such as silicon germanium, SGOI (silicon germanium on insulator), indium antimonide, lead telluride, indium arsenide, indium phosphide, gallium arsenide or gallium antimonide. In some example embodiments, the substrate 100 may include a base substrate and an epitaxial layer formed on the base substrate.

First and second memory cells 11 and 12 may be formed on the substrate 100 of the memory cell area CELL. The first and second memory cells 11 and 12 may be arranged in sequence along the second direction Y. The first and second memory cells 11 and 12 may correspond to the unit memory cells 10 of FIG. 2.

The first active patterns A11 to A14 may be formed on the substrate 100 of the memory cell area CELL. For example, the first active patterns A11 to A14 may be formed in each of the first and second memory cells 11 and 12. The first active patterns A11 to A14 may be spaced apart from each other, may parallel to each other, and may extend in the first direction X. For example, the first active patterns A11 to A14 may include the first memory active pattern A11, the second memory active pattern A12, the third memory active pattern A13, and the fourth memory active pattern A14 which extend in the first direction X and are arranged sequentially in the second direction Y.

Each of the first and second memory cells 11 and 12 may include one NFET area and one PFET area adjacent to each other in the second direction Y. For example, each of the first memory active pattern A11 and the fourth memory active pattern A14 may be used as a channel area of the PFET. Each of the second memory active pattern A12 and the third memory active pattern A13 may be used as a channel area of the NFET. Each of the first and second memory cells 11 and 12 may have the first unit cell height CH1 in the second direction Y.

In some example embodiments, the first and second memory cells 11 and 12 may have a plane-symmetrical relationship with each other around a plane (XZ plane) intersecting the second direction Y. For example, the first active patterns A11 to A14 of the first memory cell 11 may be arranged sequentially along the second direction Y, while the first active patterns A11 to A14 of the second memory cell 12 may be arranged sequentially along a direction-Y opposite to the second direction Y.

First and second upper peripheral cells 21 and 22 may be formed on the substrate 100 of the first area I of the peripheral circuit area PERI. The first and second upper peripheral cells 21 and 22 may be arranged sequentially along the second direction Y. In some example embodiments, the first upper peripheral cell 21 and the first memory cell 11 may be arranged along the first direction X, while the second upper peripheral cell 22 and the second memory cell 12 may be arranged along the first direction X. The first and second upper peripheral cells 21 and 22 may correspond to the first unit peripheral cells 20 of FIG. 2.

The second active patterns A21 and A22 may be formed on the substrate 100 of the first area I. For example, the second active patterns A21 and A22 may be formed within each of the first and second upper peripheral cells 21 and 22. The second active patterns A21 and A22 may be spaced apart from each other, may be parallel to each other, and may extend in the first direction X. For example, the second active patterns A21 and A22 may include the first upper active pattern A21 and the second upper active pattern A22 which extend in the first direction X and are arranged sequentially in the second direction Y.

Each of the first and second upper peripheral cells 21 and 22 may include one NFET area and one PFET area adjacent to each other in the second direction Y. For example, the first upper active pattern A21 may be used as a channel area of an NFET, and the second upper active pattern A22 may be used as a channel area of a PFET. Each of the first and second upper peripheral cells 21 and 22 may have the second unit cell height CH2 in the second direction Y.

In some example embodiments, the first and second upper peripheral cells 21 and 22 may be in a plane-symmetrical relationship with each other around a plane (XZ plane) intersecting the second direction Y. For example, the second active patterns A21 and A22 of the first upper peripheral cell 21 may be arranged in sequence along the second direction Y, while the second active patterns A21 and A22 of the second upper peripheral cell 22 may be arranged in sequence along a direction-Y opposite to the second direction Y.

In some example embodiments, the second unit cell height CH2 of each of the first and second upper peripheral cells 21 and 22 may be equal to the first unit cell height CH1 of each of the first and second memory cells 11 and 12. In the present disclosure, “equal” means not only “exactly equal” but also including a slight difference that may occur due to a process margin, etc.

First to fourth lower peripheral cells 31 to 34 may be formed on the substrate 100 of the second area II of the peripheral circuit area PERI. The first to fourth lower peripheral cells 31 to 34 may be arranged sequentially along the second direction Y. In some example embodiments, the first and second lower peripheral cells 31 and 32 and the first upper peripheral cell 21 may be arranged along the first direction X, while the third and fourth lower peripheral cells 33 and 34 and the second upper peripheral cell 22 may be arranged along the first direction X. The first to fourth lower peripheral cells 31 to 34 may correspond to the second unit peripheral cells 30 of FIG. 2.

The third active patterns A31 to A34 may be formed on the substrate 100 of the second area II. For example, the third active patterns A31 to A34 may be formed within the first to fourth lower peripheral cells 31 to 34. The third active patterns A31 to A34 may be spaced apart from each other and extend in a parallel manner to each other and in the first direction X. For example, the third active patterns A31 to A34 may include the first lower active pattern A31, the second lower active pattern A32, the third lower active pattern A33, and the fourth lower active pattern A34 that extend in the first direction X and are arranged sequentially in the second direction Y.

Each of the first to fourth lower peripheral cells 31 to 34 may include one NFET area and one PFET area that are adjacent to each other in the second direction Y. For example, each of the first lower active pattern A31 and the fourth lower active pattern A34 may be used as a channel area of the NFET, and each of the second lower active pattern A32 and the third lower active pattern A33 may be used as a channel area of the PFET. Each of the first to fourth lower peripheral cells 31 to 34 may have the third unit cell height CH3 in the second direction Y.

In some example embodiments, the first and fourth lower peripheral cells 31 and 34 may be in a plane-symmetrical relationship with each other around a plane (XZ plane) intersecting the second direction Y. The second and third lower peripheral cells 32 and 33 may be in a plane-symmetrical relationship with each other around a plane (XZ plane) intersecting the second direction Y. For example, the third active patterns A31 to A34 of the first and second lower peripheral cells 31 and 32 may be arranged sequentially along the second direction Y, while the third active patterns A31 to A34 of the third and fourth lower peripheral cells 33 and 34 may be arranged sequentially along a direction-Y opposite to the second direction Y.

In some example embodiments, the third unit cell height CH3 of each of the first to fourth lower peripheral cells 31 to 34 may be smaller than the second unit cell height CH2 of each of the first and second upper peripheral cells 21 and 22. In some example embodiments, a ratio of the second unit cell height CH2 to the third unit cell height CH3 may be in a range of 1.5:1 to 3:1. For example, as illustrated, the ratio of the second unit cell height CH2 to the third unit cell height CH3 may be 2:1.

Each of the active patterns A11 to A14, A21, A22, and A31 to A34 may include an elemental semiconductor material, such as silicon (Si) or germanium (Ge). In some example embodiments, each of the active patterns A11 to A14, A21, A22, and A31 to A34 may include a compound semiconductor, for example, a group IV-IV compound semiconductor or a group III-V compound semiconductor. The group IV-IV compound semiconductor may include, for example, a binary compound including two of carbon (C), silicon (Si), germanium (Ge), and tin (Sn), a ternary compound including three thereof, or a compound obtained by doping a group IV element thereto. The group III-V compound semiconductor may include, for example, a binary compound obtained by combining one of aluminum (Al), gallium (Ga), or indium (In) as a group III element and one of phosphorus (P), arsenic (As), or antimony (Sb) as a group V element with each other, a ternary compound obtained by combining two of aluminum (Al), gallium (Ga), and/or indium (In) as a group III element and one of phosphorus (P), arsenic (As), or antimony (Sb) as a group V with each other, or a quaternary compound obtained by combining aluminum (Al), gallium (Ga), and indium (In) as a group III element with one of phosphorus (P), arsenic (As), or antimony (Sb) as a group V.

In some example embodiments, each of the active patterns A11 to A14, A21, A22, and A31 to A34 may include a plurality of bridge patterns 111 to 114 which may be sequentially stacked on the substrate 100 and extend in the first direction X. The plurality of bridge patterns 111 to 114 may be spaced apart from each other in a third direction Z intersecting the first direction X and the second direction Y. The plurality of bridge patterns 111 to 114 may be used as a channel area of a multi-bridge channel field effect transistor (MBCFET®) including a multi-bridge channel. The number of bridge patterns included in each of the active patterns A11 to A14, A21, A22, and A31 to A34 is only example and is not limited to what is illustrated.

In some example embodiments, each of the active patterns A11 to A14, A21, A22, and A31 to A34 may include a fin pattern 110 that protrudes from an upper surface of the substrate 100 and extends in the first direction X. A stack of the plurality of bridge patterns 111 to 114 may be spaced apart from the fin pattern 110 in the third direction Z. The fin pattern 110 may be formed by etching a portion of the substrate 100 or may be an epitaxial layer grown from the substrate 100.

The field insulating film 105 may be formed on the substrate 100. The field insulating film 105 may cover at least a portion of a side surface of the fin pattern 110. The field insulating film 105 may include, but is not limited to, at least one of silicon oxide, silicon nitride, silicon oxynitride, or a combination thereof.

The first gate structures G1 may be formed on the substrate 100 of the memory cell area CELL. The first gate structures G1 may extend in the second direction Y and may be spaced apart from each other in the first direction X. The first gate structures G1 may intersect with the first active patterns A11 to A14. For example, the bridge patterns 111 to 114 of each of the first active patterns A11 to A14 may extend in the first direction X to extend through the first gate structures G1. The number and arrangement of the first gate structures G1 are merely examples and are not limited to those illustrated.

The second gate structures G2 may be formed on the substrate 100 of the first area I. The second gate structures G2 may extend in the second direction Y and may be spaced apart from each other in the first direction X. The second gate structures G2 may intersect with the second active patterns A21 and A22. For example, the bridge patterns 111 to 114 of each of the second active patterns A21 and A22 may extend in the first direction X to extend through the second gate structures G2. The number and arrangement of the second gate structures G2 are merely examples and are not limited to those illustrated.

The third gate structures G3 may be formed on the substrate 100 of the second area II. The third gate structures G3 may extend in the second direction Y and may be spaced apart from each other in the first direction X. The third gate structures G3 may intersect with the third active patterns A31 to A34. For example, the bridge patterns 111 to 114 of each of the third active patterns A31 to A34 may extend in the first direction X to extend through the third gate structures G3. The number and arrangement of the third gate structures G3 are merely examples and are not limited to those illustrated.

In some example embodiments, a first cutting pattern CT1 defining the second gate structures G2 of each of the first and second upper peripheral cells 21 and 22 may be formed. For example, one first cutting pattern CT1 may be positioned at a boundary between the first upper peripheral cell 21 and the second upper peripheral cell 22 so as to extend in the first direction X to cut the second gate structures G2. Furthermore, the second gate structures G2 of each of the first and second upper peripheral cells 21 and 22 may be defined by two first cutting patterns CT1 adjacent to each other in the second direction Y. In this case, the second unit cell height CH2 may be defined as a distance between centers of the two adjacent first cutting patterns CT1.

In some example embodiments, the first cutting pattern CT1 and a second cutting pattern CT2 defining the third gate structures G3 of each of the first to fourth lower peripheral cells 31 to 34 may be formed. For example, one first cutting pattern CT1 may be positioned at a boundary between the second lower peripheral cell 32 and the third lower peripheral cell 33 so as to extend in the first direction X to cut the third gate structures G3. For example, one second cutting pattern CT2 may be positioned at a boundary between the first lower peripheral cell 31 and the second lower peripheral cell 32 so as to extend in the first direction X to cut the third gate structures G3, while another second cutting pattern CT2 may be positioned at a boundary between the third lower peripheral cell 33 and the fourth lower peripheral cell 34 so as to extend in the first direction X to cut the third gate structures G3. Furthermore, the third gate structures G3 of each of the first to fourth lower peripheral cells 31 to 34 may be defined by one first cutting pattern CT1 and one second cutting pattern CT2 adjacent to each other in the second direction Y. In this case, the third unit cell height CH3 may be defined as a distance between centers of the first cutting pattern CT1 and the second cutting pattern CT2 adjacent to each other.

Each of the first cutting pattern CT1 and the second cutting pattern CT2 may include an insulating material, for example, at least one of silicon oxide, silicon nitride, silicon oxynitride, silicon oxycarbide, silicon boron nitride, silicon carbon nitride, silicon oxycarbonitride, or combinations thereof. However, example embodiments of the present disclosure are not limited thereto.

In some example embodiments, each of the gate structures G1 to G3 may include a gate dielectric film 120, a gate electrode 130, a gate spacer 140, and a gate capping film 150.

The gate dielectric film 120 may be interposed between each of the active patterns A11 to A14, A21, A22, and A31 to A34 and the gate electrode 130. The gate dielectric film 120 may include a dielectric material, for example, at least one of silicon oxide, silicon oxynitride, silicon nitride, or a high-k material having a dielectric constant greater than that of silicon oxide.

In some example embodiments, the gate dielectric film 120 may include an interfacial film 121 and a high-k dielectric film 122 sequentially stacked on each of the active patterns A11 to A14, A21, A22, and A31 to A34.

The interfacial film 121 may surround a perimeter of each of the bridge patterns 111 to 114. For example, the interfacial film 121 may conformally extend along the perimeter of each of the bridge patterns 111 to 114. The interfacial film 121 may further extend along and on the fin pattern 110 not covered with the field insulating film 105. In some example embodiments, the interfacial film 121 may include an oxide film formed by oxidizing a surface of each of the bridge patterns 111 to 114 and/or the fin pattern 110. For example, when each of the bridge patterns 111 to 114 is a silicon pattern, the interfacial film 121 may include a silicon oxide film.

The high-k dielectric film 122 may surround a perimeter of the interfacial film 121. Furthermore, a portion of the high-k dielectric film 122 may be interposed between the gate electrode 130 and the gate spacer 140. For example, the high-k dielectric film 122 may conformally extend along a profile of a perimeter of the interfacial film 121 and an inner side surface of the gate spacer 140. Furthermore, the high-k dielectric film 122 may further extend along and on an upper surface of the field insulating film 105.

In some example embodiments, the high-k dielectric film 122 may include a high-k material having a dielectric constant greater than that of silicon oxide. The high dielectric constant material may include at least one of, for example, hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OxNy), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) or combinations thereof. However, example embodiments of the present disclosure are not limited thereto.

The gate electrode 130 may extend in an elongate manner in the second direction Y to intersect with a corresponding one of the active patterns A11 to A14, A21, A22, and A31 to A34. The bridge patterns 111 to 114 of each of the active patterns A11 to A14, A21, A22, and A31 to A34 may extend in the first direction X to extend through the gate electrode 130. The gate electrode 130 may include a conductive material, for example, at least one of TiN, WN, TaN, Ru, TiC, TaC, Ti, Ag, Al, TiAl, TiAlN, TiAlC, TaCN, TaSiN, Mn, Zr, W, Al, or a combination thereof. However, example embodiments of the present disclosure are not limited thereto. The gate electrode 130 may be formed in a replacement process. However, example embodiments of the present disclosure are not limited thereto.

The gate electrode 130 is shown as being embodied as a single film. However, this is only an example, and the gate electrode 130 may be a multi-film formed by stacking a plurality of conductive films. For example, the gate electrode 130 may include a work function control film that controls a work function, and a filling conductive film that fills a space defined by the work function control film. The work function control film may include, for example, at least one of TiN, TaN, TiC, TaC, TiAlC, or a combination thereof. The filling conductive film may include, for example, W or Al.

The gate spacer 140 may extend along a side surface of the gate electrode 130. The bridge patterns 111 to 114 of each of the active patterns A11 to A14, A21, A22, and A31 to A34 may extend in the first direction X to extend through the gate spacer 140. The gate spacer 140 may include an insulating material including at least one of silicon oxide, silicon nitride, silicon oxynitride, silicon oxycarbide, silicon boron nitride, silicon boron carbonitride, silicon oxycarbonitride, or combinations thereof. However, example embodiments of the present disclosure are not limited thereto.

The gate capping film 150 may extend along and on an upper surface of the gate electrode 130. The gate capping film 150 may include an insulating material including at least one of silicon oxide, silicon nitride, silicon oxynitride, silicon oxycarbide, silicon boron nitride, silicon boron carbonitride, silicon oxycarbonitride, or combinations thereof. However, example embodiments of the present disclosure are not limited thereto.

In some example embodiments, each of the gate structures G1 to G3 may further include an inner spacer 145. The inner spacer 145 may be formed on a portion of a side surface of the gate electrode 130 between adjacent ones of the bridge patterns 111 to 114. Furthermore, the inner spacer 145 may be formed on a portion of the side surface of the gate electrode 130 between the fin pattern 110 and the stack of the bridge patterns 111 to 114.

In some example embodiments, a portion of the gate dielectric film 120 may be interposed between the gate electrode 130 and the inner spacer 145. For example, a portion of the high-k dielectric film 122 may extend further along and on an inner side surface of the inner spacer 145.

The first source/drain areas SD1 may be disposed in the first active patterns A11 to A14, respectively, and on the side surface of each of the first gate structures G1. The bridge patterns 111 to 114 of the first active patterns A11 to A14 may extend through the gate electrode 130 and the gate spacer 140 so as to contact the first source/drain area SD1. The first source/drain area SD1 may be isolated from the gate electrode 130 of the first gate structures G1 via the gate dielectric film 120, the gate spacer 140, and/or the inner spacer 145.

The second source/drain areas SD2 may be disposed in the second active patterns A21 and A22, respectively, and on the side surface of each of the second gate structures G2. The bridge patterns 111 to 114 of the second active patterns A21 and A22 may extend through the gate electrode 130 and the gate spacer 140 so as to contact the second source/drain area SD2. The second source/drain area SD2 may be isolated from the gate electrode 130 of the second gate structures G2 via the gate dielectric film 120, the gate spacer 140, and/or the inner spacer 145.

The third source/drain areas SD3 may be disposed in the third active patterns A31 to A34, respectively, and on the side surface of each of the third gate structures G3. The bridge patterns 111 to 114 of the third active patterns A31 to A34 may extend through the gate electrode 130 and the gate spacer 140 so as to contact the third source/drain area SD3. The third source/drain area SD3 may be isolated from the gate electrode 130 of the third gate structures G3 by the gate dielectric film 120, the gate spacer 140, and/or the inner spacer 145.

In some example embodiments, each of the first to third source/drain areas SD1 to SD3 may include an epitaxial layer doped with an impurity. For example, the first source/drain area SD1 may include an epitaxial pattern grown from the first active patterns A11 to A14 using an epitaxial growth method. For example, the second source/drain area SD2 may include an epitaxial pattern grown from the second active patterns A21 and A22 using an epitaxial growth method. For example, the third source/drain area SD3 may include an epitaxial pattern grown from the third active patterns A31 to A34 using an epitaxial growth method.

In some example embodiments, each of the first to third source/drain areas SD1 to SD3 may include a first epitaxial layer 161 and a second epitaxial layer 162 that are sequentially stacked. The first epitaxial layer 161 may extend along and on the upper surface of the fin pattern 110 and a side surface of each of the bridge patterns 111 to 114. The first epitaxial layer 161 may serve as a seed layer for growing the second epitaxial layer 162. The impurity concentration of the second epitaxial layer 162 may be greater than the impurity concentration of the first epitaxial layer 161.

The interlayer insulating film 190 may be formed on the substrate 100 and the field insulating film 105. The interlayer insulating film 190 may be formed to fill a space on an outer side surface of each of the gate structures G1 to G3. The interlayer insulating film 190 may cover the first to third source/drain areas SD1 to SD3.

The interlayer insulating film 190 may include at least one of, for example, silicon oxide, silicon nitride, silicon oxynitride, silicon oxycarbide, silicon boron nitride, silicon boron carbonitride, silicon oxycarbonitride, or a low-k material having a dielectric constant lower than that of silicon oxide. The low-k material may include, but is not limited to, at least one of FOX (Flowable Oxide), TOSZ (Tonene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, or combinations thereof.

The source/drain contact 180 may contact the first to third source/drain areas SD1 to SD3. For example, the source/drain contact 180 may extend in the third direction Z to extend through the interlayer insulating film 190 and may contact the first to third source/drain areas SD1 to SD3.

The wiring structure WS may be formed on the interlayer insulating film 190. The wiring structure WS may include an inter-wiring insulating film ID and wiring patterns WP within the inter-wiring insulating film ID. The wiring patterns WP may be insulated from each other via the inter-wiring insulating film ID. The number, shape, and arrangement of the wiring patterns WP are merely examples and are not limited to those illustrated.

The wiring patterns WP may be electrically connected to the source/drain contact 180 and/or the gate electrode 130. For example, a via pattern VP connecting some of the wiring patterns WP to the source/drain contact 180 may be formed. In some example embodiments, for example, a gate contact GC connecting the others of the wiring patterns WP to the gate electrode 130 may be formed.

In some example embodiments, a width of each of the second active patterns A21 and A22 may be larger than a width of each of the third active patterns A31 to A34. In this regard, the width means a length in the second direction Y. For example, as illustrated in FIG. 8, a width W11 of the first upper active pattern A21 may be larger than each of a width W21 of the first lower active pattern A31 and a width W22 of the second lower active pattern A32.

In some example embodiments, the width W11 of the first upper active pattern A21 and the width W12 of the second upper active pattern A22 may be equal to each other. It is illustrated that a first distance D11 by which the first upper active pattern A21 of the second upper peripheral cell 22 and the second upper active pattern A22 of the second upper peripheral cell 22 are spaced from each other is equal to a second distance D12 by which the second upper active pattern A22 of the first upper peripheral cell 21 and the second upper active pattern A22 of the second upper peripheral cell 22 are spaced from each other. However, this is only an example. In another example, the first distance D11 and the second distance D12 may be different from each other as needed.

In some example embodiments, the width W21 of the first lower active pattern A31 and the width W22 of the second lower active pattern A32 may be equal to each other. It is illustrated that a third distance D21 by which the first lower active pattern A31 and the second lower active pattern A32 are spaced apart from each other is equal to a fourth distance D22 by which the second lower active pattern A32 and the third lower active pattern A33 are spaced apart from each other. However, this is only an example. It should be understood that the third distance D21 and the fourth distance D22 may be different from each other, as needed.

In some example embodiments, the first upper active pattern A21 may overlap at least a portion of the first lower active pattern A31 and at least a portion of the second lower active pattern A32 in the first direction X. In some example embodiments, the second upper active pattern A22 may overlap at least a portion of the third lower active pattern A33 and at least a portion of the fourth lower active pattern A34 in the first direction X.

In some example embodiments, the first upper active pattern A21 may be connected to the first lower active pattern A31 and the second lower active pattern A32 in the first direction X. For example, the peripheral circuit area PERI may include a third area III interposed between the first area I and the second area II. Furthermore, a first connection pattern CP1 may be formed on the substrate 100 of the third area III. The first connection pattern CP1 may connect the first upper active pattern A21, the first lower active pattern A31, and the second lower active pattern A32 to each other. For example, as illustrated in FIG. 8, the first connection pattern CP1 may include a first portion P1, a second portion P2, and a third portion P3. The first portion P1 may extend in the first direction X to connect the first upper active pattern A21 and the first lower active pattern A31 to each other. The second portion P2 may extend in the first direction X to connect the first upper active pattern A21 and the second lower active pattern A32 to each other. The third portion P3 may extend in the second direction Y to connect the first portion P1 and the second portion P2 to each other. Although not specifically illustrated, the first connection pattern CP1 may include the fin pattern 110 and/or the bridge patterns 111 to 114 as described above.

In some example embodiments, the second upper active pattern A22 may be connected to the third lower active pattern A33 and the fourth lower active pattern A34 in the first direction X. For example, a second connection pattern CP2 may be formed on the substrate 100 of the third area III. The second connection pattern CP2 may connect the second upper active pattern A22, the third lower active pattern A33, and the fourth lower active pattern A34 to each other. Because the second connection pattern CP2 may be similar to the first connection pattern CP1, a detailed description thereof will be omitted below.

In some example embodiments, a dummy gate structure DG may be formed on the substrate 100 of the third area III. The dummy gate structure DG may extend in the second direction Y so as to intersect the first connection pattern CP1 and the second connection pattern CP2. Although not specifically illustrated, the dummy gate structure DG may include the gate dielectric film 120, the gate electrode 130, the gate spacer 140, the inner spacer 145, the gate capping film 150, etc. as described above. The number and arrangement of the dummy gate structures DG are merely examples and are not limited to those illustrated.

In some example embodiments, a width of the third area III in the first direction X may be in a range of 1CPP to 3CPP. In this regard, the CPP (Contacted Poly Pitch) may be defined as a sum of a spacing between adjacent gate structures and a width of one of the adjacent gate structures, or a spacing between a center of one gate structure and a center of another gate structure adjacent thereto. For example, the number of dummy gate structures DG arranged in the third area III may be in a range of 1 to 3.

As the second unit cell height CH2 and the third unit cell height CH3 are different from each other, the third area III may include a transition area of the NFET and/or a transition area of the PFET. For example, within the third area III, the NFET area and the PFET area may partially overlap in the first direction X.

In one example, as described above, each of the first upper active pattern A21 and the first lower active pattern A31 may be used as the channel area of the NFET. The second lower active pattern A32 may be used as the channel area of the PFET. In this case, each of the first portion P1 and the third portion P3 of the first connection pattern CP1 may include an n-type impurity (e.g., P, Sb or As), and the second portion P2 of the first connection pattern CP1 may include a p-type impurity (e.g., B, In, Ga or Al).

In one example, as described above, each of the second upper active pattern A22 and the third lower active pattern A33 may be used as the channel area of thea PFET, and the fourth lower active pattern A34 may be used as the channel area of the NFET. In this case, each of the second portion P2 and the third portion P3 of the second connection pattern CP2 may include a p-type impurity (e.g., B, In, Ga, or Al), and the first portion P1 of the second connection pattern CP2 may include an n-type impurity (e.g., P, Sb, or As).

In some example embodiments, the wiring patterns WP may include a first power wiring PW1 and a second power wiring PW2 in the peripheral circuit area PERI. Each of the first power wiring PW1 and the second power wiring PW2 may extend in the first direction X. A first power voltage (e.g., V_{SS}) may be applied to the first power wiring PW1, and a second power voltage (e.g., V_{DD}) different from the first power voltage may be applied to the second power wiring PW2. The first power wiring PW1 may be electrically connected to the first area I and the second area II and provide the first power voltage thereto. The second power wiring PW2 may be electrically connected to the first area I and the second area II and provide the second power voltage thereto.

In some example embodiments, the first power wiring PW1 may be connected to the ground node V_{SS} of each of the unit memory cells 10 of FIG. 3, and the second power wiring PW2 may be connected to the power node V_{DD} of each of the unit memory cells 10 of FIG. 3.

In some example embodiments, the first power wirings PW1 and the second power wirings PW2 may be alternately arranged with each other along the second direction Y.

In some example embodiments, one first upper active pattern A21 and one second upper active pattern A22 may be disposed between two first power wirings PW1 adjacent to each other in the second direction Y. The first power wiring PW1 may extend across the first area I and the second area II so as to be commonly connected to the first area I and the second area II. For example, one first power wiring PW1 may be positioned at a boundary between the first upper peripheral cell 21 and the second upper peripheral cell 22 and a boundary between the second lower peripheral cell 32 and the third lower peripheral cell 33 in a plan view.

In some example embodiments, two first upper active patterns A21 (or two second upper active patterns A22) may be disposed between two second power wirings PW2 adjacent to each other in the second direction Y. The second power wiring PW2 may extend across the first area I and the second area II so as to be commonly connected to the first area I and the second area II. For example, one second power wiring PW2 may be disposed in an area between the first upper active pattern A21 and the second upper active pattern A22 in the first upper peripheral cell 21 and at a boundary between the first lower peripheral cell 31 and the second lower peripheral cell 32 in the plan view.

As the integration level of a standard cell used in the semiconductor device continues to improve, an integrated unit peripheral circuit cell relative to a unit memory cell may be used. For example, a semiconductor memory device having a ratio of the cell height of the unit memory cell and the cell height of the unit peripheral circuit cell in a range of 4:6 or 4:6.5 has been proposed. However, in such a unit peripheral circuit cell, a relatively large area may be needed as a dummy area in order to form the peripheral circuit. Further, the unit peripheral circuit cell may not satisfy the desired performance. For example, in the input/output circuit of the SRAM (e.g., 4 in FIG. 1), an upper input/output circuit (upper I/O circuit) area adjacent to the memory cell array (e.g., 1 in FIG. 1) may need higher current drivability than current drivability that a lower input/output circuit (lower I/O circuit) area, which is relatively distant from the memory cell array needs. However, there is a problem that a high NOF (Number of Fingers) is desired in the integrated unit peripheral circuit cell to satisfy such higher current drivability of the upper input/output circuit.

According to some example embodiments, a semiconductor device may provide the first area I that provides relatively high current drivability and the second area II that is relatively more highly integrated, thereby providing an optimized or improved peripheral circuit area as needed. Specifically, as described above, the second active patterns A21 and A22 having the relatively larger widths W11 and W12 may be formed in the first area I adjacent to the memory cell area CELL, while the third active patterns A31 to A34 having relatively smaller widths W21 and W22 may be formed in the second area II that is spaced apart further from the memory cell area CELL than the first area I. Thus, for example, the first area I may provide high current drivability in the upper input/output circuit of the SRAM, while the second area II may improve the integration level in the lower input/output circuit of the SRAM. Thus, the semiconductor device with improved performance and integration level may be provided.

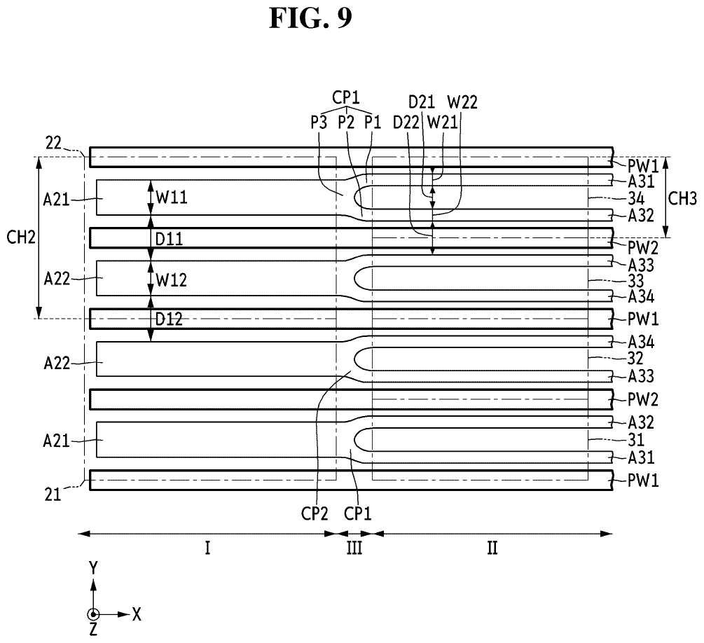

FIGS. 9 to 12 are other various example layout diagrams for illustrating semiconductor devices according to some example embodiments, respectively. For convenience of description, contents duplicate with those described above using FIGS. 1 to 8 are briefly described or the descriptions thereof are omitted.

Referring to FIGS. 1 to 3 and FIG. 9, in a semiconductor device according to some example embodiments, the first distance D11 by which the first upper active pattern A21 and the second upper active pattern A22 are spaced from each other may be greater than the fourth distance D22 by which the second lower active pattern A32 and the third lower active pattern A33 are spaced from each other.

In some example embodiments, the width W11 of the first upper active pattern A21 may be smaller than a sum of the third distance D21 by which the first lower active pattern A31 and the second lower active pattern A32 are spaced apart from each other, the width W21 of the first lower active pattern A31, and the width W22 of the second lower active pattern A32.

Referring to FIGS. 1 to 3 and FIG. 10, in a semiconductor device according to some example embodiments, each of the first and fourth lower peripheral cells 31 and 34 may include the first to fourth lower active patterns A31 to A34, while each of the second and third lower peripheral cells 32 and 33 may include fifth to eighth lower active patterns A35 to A38.

The first to fourth lower active patterns A31 to A34 may be connected to the first upper active pattern A21 in the first direction X. The fifth to eighth lower active patterns A35 to A38 may be connected to the second upper active pattern A22 in the first direction X.

For example, each of the first, second, seventh, and eighth lower active patterns A31, A32, A37, and A38 may be used as the channel area of the NFET. Each of the third, fourth, fifth, and sixth lower active patterns A33, A34, A35, and A36 may be used as the channel areas of the PFET.

Referring to FIG. 1 to FIG. 3 and FIG. 11, in a semiconductor device according to some example embodiments, the first distance D11 by which the first upper active pattern A21 and the second upper active pattern A22 are spaced apart from each other may be smaller than the fourth distance D22 by which the second lower active pattern A32 and the third lower active pattern A33 are spaced apart from each other.

In some example embodiments, the width W11 of the first upper active pattern A21 may be larger than a sum of the third distance D21 by which the first lower active pattern A31 and the second lower active pattern A32 are spaced apart from each other, the width W21 of the first lower active pattern A31, and the width W22 of the second lower active pattern A32.

Referring to FIG. 1 to FIG. 3 and FIG. 12, in a semiconductor device according to some example embodiments, each of the first and second upper peripheral cells 21 and 22 may include the first to third upper active pattern A21 to A23.

The first upper active pattern A21 may be connected to the first lower active pattern A31 in the first direction X. The second upper active pattern A22 may be connected to the second lower active pattern A32 and the third lower active pattern A33 in the first direction X. The third upper active pattern A23 may be connected to the fourth lower active pattern A34 in the first direction X.

In some example embodiments, a portion of the second power wiring PW2 may be positioned at a boundary between the first and second upper peripheral cells 21 and 22. The second power wiring PW2 positioned at a boundary between the first and second upper peripheral cells 21 and 22 and the first power wiring PW1 positioned at a boundary between the second and third lower peripheral cells 32 and 33 may be arranged along the first direction X.

In some example embodiments, each of the second power wiring PW2 positioned at a boundary between the first and second lower peripheral cells 31 and 32 and the second power wiring PW2 positioned at a boundary between the third and fourth lower peripheral cells 33 and 34 may not extend along the first area I.

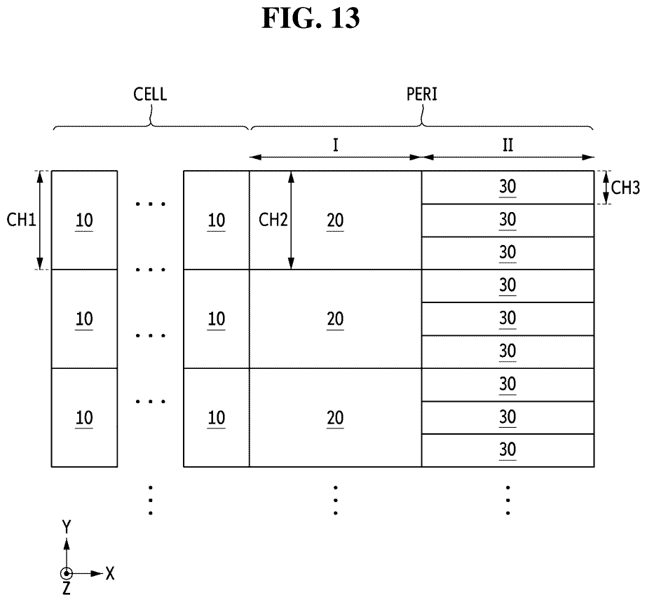

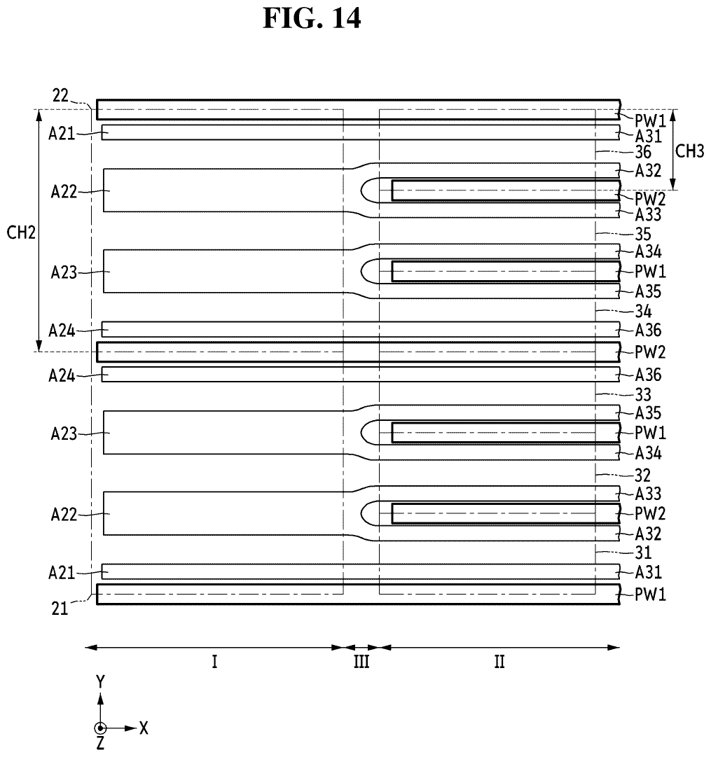

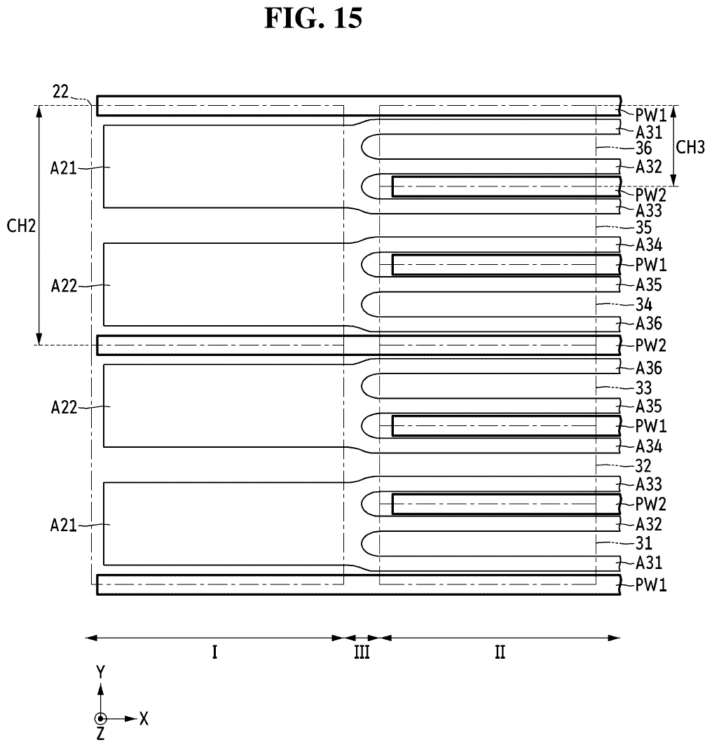

FIG. 13 is a conceptual plan view illustrating a semiconductor device according to some example embodiments. FIG. 14 and FIG. 15 are various example layout diagrams illustrating the semiconductor device of FIG. 13. For convenience of description, contents duplicate with those described above using FIGS. 1 to 8 are briefly described or the descriptions thereof are omitted.

Referring to FIG. 1 to FIG. 3 and FIG. 13 to FIG. 15, in some example embodiments of the semiconductor device, the ratio of the second unit cell height CH2 and the third unit cell height CH3 may be 3:1.

For example, as illustrated in FIG. 14 and FIG. 15, the first area I may include first and second upper peripheral cells 21 and 22 arranged sequentially along the second direction Y. The second area II may include first to sixth lower peripheral cells 31 to 36 corresponding to the first and second upper peripheral cells 21 and 22 and arranged sequentially along the second direction Y. Furthermore, the first to sixth lower active patterns A31 to A36 may be formed within the first to sixth lower peripheral cells 31 to 36.

Referring to FIG. 1 to FIG. 3, FIG. 13 and FIG. 14, in a semiconductor device according to some example embodiments, each of the first and second upper peripheral cells 21 and 22 may include first to fourth upper active patterns A21 to A24.

The first upper active pattern A21 may be connected to the first lower active pattern A31 in the first direction X. The second upper active pattern A22 may be connected to the second lower active pattern A32 and the third lower active pattern A33 in the first direction X. The third upper active pattern A23 may be connected to the fourth lower active pattern A34 and the fifth lower active pattern A35 in the first direction X. The fourth upper active pattern A24 may be connected to the sixth lower active pattern A36 in the first direction X.

Referring to FIG. 1 to FIG. 3, FIG. 13, and FIG. 15, in a semiconductor device according to some example embodiments, each of the first and second upper peripheral cells 21 and 22 may include the first and second upper active patterns A21 and A22.

The first upper active pattern A21 may be connected to the first to third lower active patterns A31 to A33 in the first direction X. The second upper active pattern A22 may be connected to the fourth to sixth lower active patterns A34 to A36 in the first direction X.

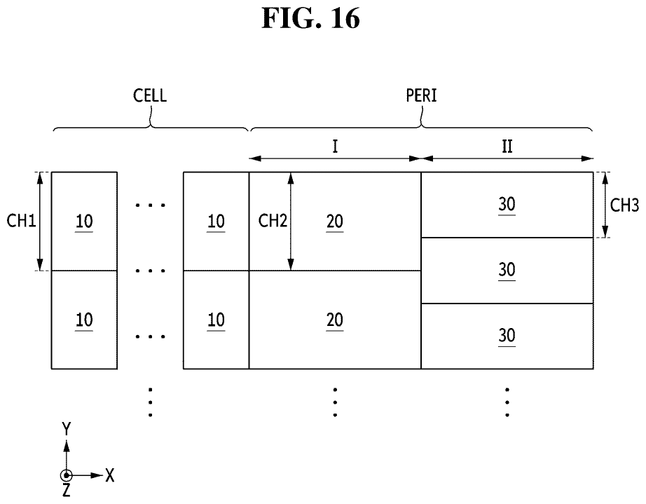

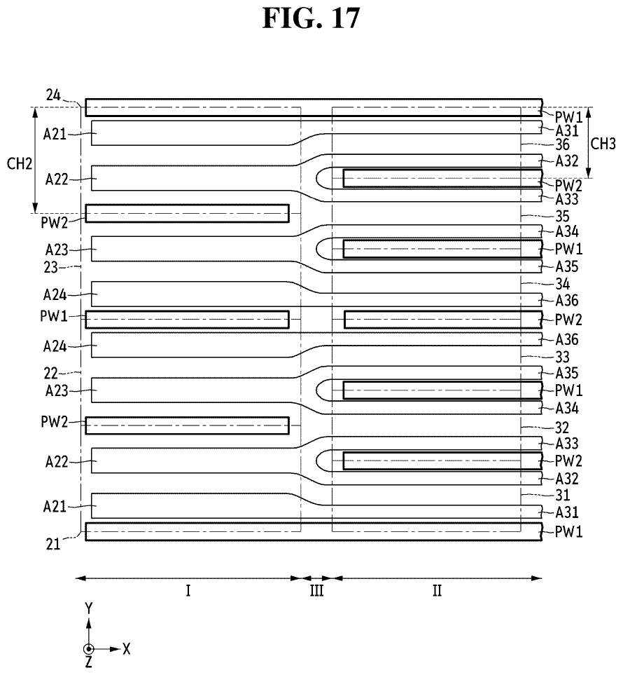

FIG. 16 is a conceptual plan view illustrating a semiconductor device according to some example embodiments. FIG. 17 is an example layout diagram illustrating the semiconductor device of FIG. 16. For convenience of description, contents duplicate with those described above using FIGS. 1 to 15 are briefly described or the descriptions thereof are omitted.

Referring to FIG. 1 to FIG. 3, FIG. 16 and FIG. 17, in some example embodiments of the semiconductor device, the ratio of the second unit cell height CH2 and the third unit cell height CH3 may be 1.5:1.

For example, as illustrated in FIG. 17, the first area I may include the first to fourth upper peripheral cells 21 to 24 arranged sequentially along the second direction Y. The second area II may include the first to sixth lower peripheral cells 31 to 36 corresponding to the first to fourth upper peripheral cells 21 to 24 and arranged sequentially along the second direction Y. Furthermore, the first to fourth upper active pattern A21 to A24 may be formed within the first to fourth upper peripheral cells 21 to 24. For example, the first and second upper active patterns A21 and A22 may be formed within the first upper peripheral cell 21. The third and fourth upper active patterns A23 and A24 may be formed within the second upper peripheral cell 22.

The first upper active pattern A21 may be connected to the first lower active pattern A31 in the first direction X. The second upper active pattern A22 may be connected to the second lower active pattern A32 and the third lower active pattern A33 in the first direction X. The third upper active pattern A23 may be connected to the fourth lower active pattern A34 and the fifth lower active pattern A35 in the first direction X. The fourth upper active pattern A24 may be connected to the sixth lower active pattern A36 in the first direction X.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although some example embodiments of the present disclosure have been described with reference to the accompanying drawings, the present disclosure is not limited to the above example embodiments, but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above are not restrictive but illustrative in all respects.

What is claimed is:

1. A semiconductor device comprising:
a cell array area including a plurality of unit memory cells arranged two-dimensionally along a first direction and a second direction intersecting each other;
a first peripheral circuit area including a plurality of first unit peripheral cells arranged along the second direction, the first peripheral circuit area and the cell array area arranged along the first direction; and
a second peripheral circuit area including a plurality of second unit peripheral cells arranged along the second direction, the first peripheral circuit area interposed between the cell array area and the second peripheral circuit area,
wherein a first unit cell height of each of the unit memory cells in the second direction and a second unit cell height of each of the first unit peripheral cells in the second direction are equal to each other, and
wherein a third unit cell height of each of the second unit peripheral cells in the second direction is smaller than the second unit cell height.

2. The semiconductor device of claim 1, further comprising:
a bit-line and a complementary bit-line extending in a parallel manner with each other and in the first direction; and
a word-line extending in the second direction,
wherein each of the unit memory cells includes
a first inverter and a second inverter constituting a latch circuit,
a first pass transistor connecting an output node of the first inverter to the bit-line, and
a second pass transistor connecting an output node of the second inverter to the complementary bit-line, and
wherein the word-line is connected to a gate of the first pass transistor and a gate of the second pass transistor.

3. The semiconductor device of claim 2, wherein the first peripheral circuit area is electrically connected to the cell array area via the bit-line and the complementary bit-line.

4. The semiconductor device of claim 1, wherein a ratio of the second unit cell height and the third unit cell height is in a range of 1.5:1 to 3:1.

5. The semiconductor device of claim 4, wherein the ratio of the second unit cell height and the third unit cell height is 2:1.

6. The semiconductor device of claim 1, wherein
each of the first unit peripheral cells includes a first upper active pattern and a second upper active pattern extending in the first direction and spaced apart from each other in the second direction,
each of the second unit peripheral cells includes a first lower active pattern and a second lower active pattern extending in the first direction and spaced apart from each other in the second direction, and
a width of each of the first and second upper active patterns in the second direction is larger than a width of each of the first and second lower active patterns in the second direction.

7. The semiconductor device of claim 6, wherein
each of the first upper active pattern and the first lower active pattern includes a channel area of an NFET,
each of the second upper active pattern and the second lower active pattern includes a channel area of a PFET.

8. The semiconductor device of claim 6, wherein each of the first and second upper active patterns and the first and second lower active patterns includes a plurality of bridge patterns spaced apart from each other in a third direction intersecting the first direction and the second direction.

9. The semiconductor device of claim 6, wherein the first upper active pattern is connected to the first lower active pattern and the second lower active pattern in the first direction.

10. The semiconductor device of claim 1, further comprising:
first power wirings and second power wirings in the first peripheral circuit area and the second peripheral circuit area and extending in the first direction,
wherein the first power wirings and the second power wirings are alternately arranged with each other in the second direction.

11. A semiconductor device comprising a memory cell, an upper peripheral cell, and a first lower peripheral cell sequentially arranged along a first direction, the semiconductor device comprising:
a substrate;
a first upper active pattern and a second upper active pattern on a first area of the substrate, at which the upper peripheral cell is provided, the first upper active pattern and the second upper active pattern extending in the first direction and being spaced apart from each other in a second direction intersecting the first direction;
a first gate structure on the first upper active pattern and the second upper active pattern and extending in the second direction;
a first lower active pattern and a second lower active pattern on a second area of the substrate, at which the first lower peripheral cell is provided, the first lower active pattern and the second lower active pattern extending in the first direction and being spaced apart from each other in the second direction; and
a second gate structure on the first lower active pattern and the second lower active pattern and extending in the second direction,
wherein a first unit cell height of the memory cell in the second direction and a second unit cell height of the upper peripheral cell in the second direction are equal to each other, and
wherein the first upper active pattern overlaps at least a portion of the first lower active pattern and at least a portion of the second lower active pattern in the first direction.

12. The semiconductor device of claim 11, further comprising:
a second lower peripheral cell such that the first lower peripheral cell and the second lower peripheral cell are arranged along the second direction; and
a third lower active pattern and a fourth lower active pattern on a third area of the substrate, at which the second lower peripheral cell is provided, the third lower active pattern and the fourth lower active pattern extending in the first direction and being spaced apart from each other in the second direction, and
wherein the second upper active pattern overlaps at least a portion of the third lower active pattern and at least a portion of the fourth lower active pattern in the first direction.

13. The semiconductor device of claim 12, wherein
each of the first upper active pattern, the first lower active pattern and the fourth lower active pattern includes a channel area of a NFET, and
each of the second upper active pattern, the second lower active pattern, and the third lower active pattern includes a channel area of a PFET.

14. The semiconductor device of claim 11, wherein a width of each of the first and second upper active patterns in the second direction is larger than a width of each of the first and second lower active patterns in the second direction.

15. The semiconductor device of claim 11, wherein the first upper active pattern is connected to the first lower active pattern and the second lower active pattern in the first direction.

16. The semiconductor device of claim 11, further comprising:
a first power wiring extending in the first direction and configured to receive a first power voltage; and
a second power wiring extending in the first direction and configured to receive a second power voltage different from the first power voltage,
wherein, in a plan view of the semiconductor device, the first upper active pattern, the first lower active pattern, and the second lower active pattern are between the first power wiring and the second power wiring, and
wherein in the plan view, the second power wiring is between the first upper active pattern and the second upper active pattern.

17. A semiconductor device comprising a first area and a second area arranged along a first direction, and a third area interposed between the first area and the second area, the semiconductor device comprising:
a substrate;
first and second upper active patterns on a first portion of the substrate corresponding to the first area, the first and second upper active patterns extending in the first direction and arranged along a second direction intersecting the first direction;
a first gate structure on the first and second upper active patterns and extending in the second direction;
first to fourth lower active patterns on a second portion of the substrate corresponding to the second area, the first to fourth lower active patterns extending in the first direction and arranged sequentially along the second direction;
a second gate structure on the first to fourth lower active patterns and extending in the second direction;
a first connection pattern on a third portion of the substrate corresponding to the third area, the first connection pattern connecting the first upper active pattern, the first lower active pattern, and the second lower active pattern to each other;
a second connection pattern on the third portion of the substrate corresponding to the third area, the second connection pattern connecting the second upper active pattern, the third lower active pattern, and the fourth lower active pattern to each other;
a first power wiring extending in the first direction across the first to third areas and configured to receive a first power voltage; and
a second power wiring extending in the first direction across the first to third areas and configured to receive a second power voltage different from the first power voltage,
wherein each of the first upper active pattern, the first lower active pattern, and the fourth lower active pattern includes a channel area of an NFET, and
wherein each of the second upper active pattern, the second lower active pattern, and the third lower active pattern includes a channel area of a PFET.

18. The semiconductor device of claim 17, wherein in a plan view of the semiconductor device,
the first upper active pattern, the first lower active pattern, and the second lower active pattern are between the first power wiring and the second power wiring, and
the second power wiring is between the first upper active pattern and the second upper active pattern and between the second lower active pattern and the third lower active pattern.

19. The semiconductor device of claim 17, further comprising:
a dummy gate structure extending in the second direction, on the first connection pattern and the second connection pattern.

20. The semiconductor device of claim 17, wherein each of the first and second upper active patterns, the first to fourth lower active patterns, and the first and second connection patterns includes a plurality of bridge patterns spaced apart from each other in a third direction intersecting the first direction and the second direction.
